(19) United States
(12) Patent Application Publication
(10) Pub. No.: US 2020/0355410 A1
(43) Pub. Date: Nov. 12, 2020

(54) METHOD FOR REGULATING A PELTIER ELEMENT

(71) Applicant: Mahle International GmbH, Stuttgart (DE)

(72) Inventors: Juergen Gruenwald, Ludwigsburg (DE); Christian Schulze, Stuttgart (DE)

(21) Appl. No.: 16/640,373

(22) PCT Filed: Jul. 10, 2018
(86) PCT No.: PCT/EP2018/068642

§ 371 Date: Feb. 20, 2020

(30) Foreign Application Priority Data
Aug. 23, 2017 (DE) 10 2017 214 764.4

(51) Int. Cl. F25B 21/02; B60H 1/00; H01L 35/34

(52) U.S. Cl. CPC F25B 21/02; B60H 1/00478; F25B 2500/19; F25B 2321/0212; H01L 35/34

(57) ABSTRACT

The disclosure concerns a method for regulating a Peltier element. In a starting step, a starting current is applied to the Peltier element. Subsequently in a cooling step, a surface that is heat-conductively connected to the Peltier element is cooled. In the cooling step, the surface is cooled to a target temperature. After the cooling step in an adjustment step, a maintenance current is applied to the Peltier element. The maintenance current is lower than the starting current.

### CROSS-REFERENCE TO RELATED APPLICATIONS

This application claims priority to International Patent Application No. PCT/EP2018/068642 filed on Jul. 10, 2018, and also claims priority to German Patent Application DE 10 2017 214 764.4 filed on Aug. 23, 2017, the contents of each of which is hereby incorporated by reference in their entirety.

### TECHNICAL FIELD

The invention relates to a method for regulating a Peltier element for cooling a surface.

### BACKGROUND

When flowed through by a current, a Peltier element generates a temperature differential which can be utilised for example for cooling surfaces in a motor vehicle. The surface to be cooled can be for example a seating surface, an inner door surface or a console surface. The cooling output of the Peltier element can be regulated through the current flowing through the Peltier element, wherein the profile of the cooling output as a function of the current flowing through the Peltier element corresponds to an inverted parabola. The vertex of this parabola corresponds to the maximally achievable cooling output of the Peltier element with the corresponding optimal current. As soon as the current is further increased, the cooling output of the Peltier element is reduced and the excess electrical energy merges into the thermal energy.

When cooling a surface, the Peltier element is usually operated with the maximum cooling output in order to quickly and efficiently cool the surface. As soon as the surface is cooled, the Peltier element is switched off. Switching off and switching on the Peltier element can be regulated through thermal sensors such as described for example in U.S. Pat. No. 4,920,759. Here, the Peltier element is regulated dependent on the heat exchange between the surface to be cooled and a vehicle occupant. Because of this, the cooling of the surface substantially supersedes a conventionally known cooling system.

A particular travelling comfort for a vehicle occupant is reached however when the surface has a constant temperature. With the methods known from the prior art this is not realisable however.

### SUMMARY

The object of the invention therefore is to provide a method for regulating a Peltier element for cooling a surface, with which a cooling of a surface to a constant temperature is made possible.

According to the invention, this object is solved through the subject of the independent claim(s). Advantageous embodiments are subject of the dependent claims.

In a method for regulating a Peltier element, the present invention is based on the general idea of cooling a surface to a target temperature and subsequently maintain the target temperature reached. Here, a starting current is applied to the Peltier element in a starting step and subsequently the surface, connected to the Peltier element in a heat-conductive manner, cooled in a cooling step. According to the invention, the surface in the cooling step is first cooled to the target temperature. Following the cooling step, a maintenance current is applied to the Peltier element in an adjustment step, wherein the maintenance current is lower than the starting current.

In the method according to the invention, the target temperature of the surface—for example a seating surface, an inner door surface or a console surface of a motor vehicle—is reached in the cooling step. Here, the target temperature can be pre-set manually or by a vehicle occupant through a control device dependent on an ambient temperature or an interior temperature in the motor vehicle. As soon as the target temperature of the surface to be cooled is reached, the cooling step is terminated and in the adjustment step, the maintenance current is applied to the Peltier element. The target temperature can be monitored for example by way of a sensor. The maintenance current is lower than the starting current so that the surface is cooled with a reduced cooling output. The cooling output and the maintenance current are selected in such a manner that advantageously the target temperature of the surface is maintained.

According to the invention, the cooling step is carried out following the starting step, wherein the starting step can be initiated automatically—for example following a starting of the motor—or manually by a vehicle occupant.

In the method according to the invention, the surface to be cooled is cooled to the target temperature and the maintenance current for maintaining the target temperature of the surface applied, as a result of which a maximum travelling comfort for a vehicle occupant is achieved. Furthermore, the maintenance current which, compared with the starting current, is lower, is applied to the Peltier element in the adjustment step and the cooling output of the Peltier element reduced. In this way, the energy consumption of the Peltier element is also reduced. Furthermore, for carrying out the method, no conventional regulators become necessary which depending on type can be slow in response and exhibit an overshoot behaviour upon a quick regulation. Because of this, an additional electrical power consumption of the Peltier element through an overshoot behaviour of the conventional regulator can be avoided and the method according to the invention also carried out faster.

Advantageously it is provided that in the starting step the starting current to a maximum cooling output of the Peltier element is applied. The cooling output P depends on the Seebeck coefficient S_{E}, on the ohmic resistance R, on the heat transmission coefficient K_{A} of the Peltier element, on the current I and on the temperature differential ΔT on the Peltier element. The relationship can be described by the general formula:

$$P = - \frac{R}{2} * {I}^{2} + {S}_{E} * Δ T * I - {K}_{A} * Δ T$$

With the maximum cooling output, the Peltier element is quickly and efficiently brought to the target temperature so that the maximum travelling comfort for a vehicle occupant is reached even after a short cooling period. Because of the fact that the maximum cooling output does not depend on the temperature differential on the Peltier element and is always at the corresponding starting current, no elaborate re-adjusting of the starting current is necessary in the cooling step. Although the surfaces to be cooled in a motor vehicle are preferably produced from soft elastic materials with a low heat conductivity—such for example fabric, leather or plastic—, the surface to be cooled can still be brought up to the target temperature quickly and efficiently because of a low heat capacity of these materials.

In a further development of the method according to the invention, it is advantageously provided that after the cooling step and before the adjustment step the maintenance current is determined in a determination step. Preferably, the maintenance current is determined with reference to an ambient temperature and/or a temperature differential in the Peltier element and/or the target temperature and/or physical characteristics of the Peltier element and/or current operating parameters of an air conditioning system or further parameters. In this way, the maintenance current can be determined at which the target temperature of the surface to be cooled can be kept constant. In particular, an elaborate re-adjusting of the target temperature can thus be avoided and because of this the regulating expenditure reduced.

Advantageously, the maintenance current can be taken over from a stored value table. Here, the value table can contain values of the maintenance current for different ambient temperatures, different temperature differentials in the Peltier element, different target temperatures, different physical characteristics of the Peltier element, different operating parameters of an air conditioning system and further values. Dependent on these parameters, the corresponding value of the maintenance current can be taken over from the value table and the corresponding maintenance current applied to the Peltier element in the adjustment step. Alternatively, the maintenance current can also be calculated with reference to the mentioned parameters.

Advantageously it is provided in the further-developed method for regulating the Peltier element that after the adjustment step a maintenance step is carried out, wherein in the maintenance step the target temperature of the surface is kept constant.

For maintaining the target temperature on the surface to be cooled, the maintenance current on the Peltier element can be kept constant in the maintenance step. In the maintenance step, the Peltier element is operated with a maintenance output corresponding to the maintenance current, which is lower than the maximum cooling output. At the lower maintenance output, the temperature differential in the Peltier element is also reduced. At the same time, the temperature differential between the surroundings and the Peltier element is also reduced through the cooling of the surface in the cooling step and through further temperature-control systems. Accordingly, the maintenance output can be minimised and the energy requirement of the Peltier element advantageously reduced. Because of this, the maintenance output in particular with the surface to be cooled consisting of soft elastic materials with a low heat conductivity—such as for example fabric, leather or plastic—can be reduced since the surface to be cooled has already been cooled to the target temperature and has a low heat exchange with the surroundings already cooled as well. The maintenance output of the Peltier element and a dissipation loss through a heat exchange of the Peltier element with the surroundings can be advantageously offset against one another and the Peltier element operated particularly efficiently.

Altogether, the Peltier element for cooling the surface can be regulated through the method according to the invention, wherein the surface is quickly and efficiently cooled to the target temperature and the target temperature of the surface maintained. Through the method according to the invention, the travelling comfort for a vehicle occupant can be maximised.

Further important features and advantages of the invention are obtained from the subclaims, from the drawings and from the associated figure description by way of the drawings.

It is to be understood that the features mentioned above and still to be explained in the following cannot only be used in the respective combination stated but also in other combinations or by themselves without leaving the scope of the present invention.

Preferred exemplary embodiments of the invention are shown in the drawings and are explained in more detail in the following description, wherein same reference numbers relate to same or similar or functionally same components.

### BRIEF DESCRIPTION OF THE DRAWINGS

It shows, in each case schematically

FIG. 1 sequence of a method according to the invention for regulating a Peltier element;

FIG. 2 profile of a cooling output as a function of a current applied to the Peltier element in a method according to the invention.

### DETAILED DESCRIPTION

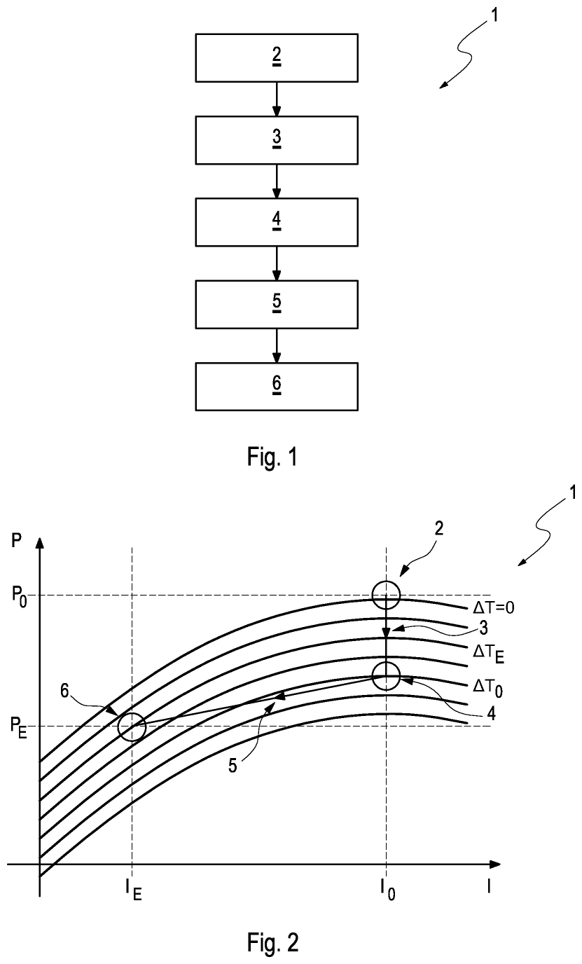

FIG. 1 shows a schematic sequence of a method 1 according to the invention for regulating a Peltier element. Firstly, a starting current is applied to the Peltier element in a starting step 2 and subsequently the surface heat-conductively connected to the Peltier element cooled to a target temperature in a cooling step 3. After the cooling step 3, a maintenance current is determined in a determination step 4. There, an ambient temperature and/or a temperature differential in the Peltier element or the target temperature and/or physical characteristics of the Peltier element and/or operating parameters of an air conditioning system and/or further parameters can be taken into account. Advantageously, the maintenance current can be taken over from a stored value table or calculated. Following the determination step 4, the maintenance current is applied to the Peltier element in an adjustment step 5, wherein the maintenance current is lower than the starting current. Following this, a maintenance step 6 is carried out in which the target temperature of the surface to be cooled is kept constant.

FIG. 2 shows a profile of a cooling output P as a function of a current I applied to the Peltier element in the method 1. The parabolas that are parallel to one another reflect the profile of the cooling output P at different temperature differentials ΔT built up in the Peltier element. Here, the temperature differentials ΔT increase from the upper parabola to the lower parabola. In the starting step 2, the starting current I₀ is applied to the Peltier element which corresponds to a maximum cooling output P₀. On the Peltier element, a temperature differential from 0 to ΔT₀ is built up. As soon as the target temperature on the surface to be cooled is reached, the maintenance current I_{E} determined in the determination step 4 is applied to the Peltier element and kept constant in the maintenance step 6. During the maintenance step 6, the temperature differential ΔT₀ decreases to a temperature differential ΔT_{E}. In the maintenance step 6, the cooling output P₀ is minimised to a maintenance output P_{E} since the surface to be cooled has already been cooled to the target temperature and has a low heat conductivity. Moreover, the surroundings around the surface to be cooled are reduced by the Peltier element itself and through further temperature control systems around the Peltier element. The maintenance output P_{E} of the Peltier element and a dissipation loss through a heat exchange of the Peltier element with the surroundings are offset against one another and the target temperature of the surface to be cooled kept constant with a minimum maintenance output P_{E} over a longer period of time.

Altogether, the Peltier element for cooling the surface can be regulated through the method 1 according to the invention, wherein the surface is quickly and efficiently cooled to the target temperature and the target temperature of the surface maintained. In this way, the maximum travelling comfort for a vehicle occupant can be achieved.

1. A method for regulating a Peltier element for cooling a surface, comprising:
in a starting step, applying a starting current to the Peltier element;
subsequently in a cooling step, cooling the surface that is heat-conductively connected to the Peltier element;
wherein in the cooling step the surface is cooled to a target temperature; and
after the cooling step in an adjustment step, applying a maintenance current to the Peltier element, wherein the maintenance current is lower than the starting current.

2. The method according to claim 1, wherein in the starting step the starting current corresponding to a maximum cooling output of the Peltier element is applied.

3. The method according to claim 1, wherein after the cooling step and before the adjustment step the maintenance current is determined in a maintenance step.

4. The method according to claim 3, wherein the maintenance current is taken over from a stored value table.

5. The method according to claim 3, wherein the maintenance current is calculated.

6. The method according to claim 1, wherein after the adjustment step a maintenance step is carried out, and wherein in the maintenance step the target temperature of the surface is kept constant.

7. The method according to claim 6, wherein in the maintenance step the maintenance current of the Peltier element is kept constant.

8. The method according to claim 6, wherein in the maintenance step a temperature differential in the Peltier element is reduced.

9. The method according to claim 6, wherein the maintenance step includes operating the Peltier element with a maintenance output, wherein the maintenance output is lower than a maximum cooling output of the Peltier element.

10. The method according to claim 9, wherein the maintenance output of the Peltier element and a dissipated loss through a heat exchange of the Peltier element with a surroundings are offset against one another.

11. The method according to claim 7, wherein the maintenance step includes reducing a temperature differential in the Peltier element.

12. The method according to claim 11, wherein the maintenance step further includes operating the Peltier element with a maintenance output that is lower than a maximum cooling output of the Peltier element.

13. The method according to claim 1, further comprising, in a maintenance step after the cooling step and before the adjustment step, determining the maintenance current with reference to at least one of an ambient temperature, a temperature differential in the Peltier element, the target temperature, physical characteristics of the Peltier element, and operating parameters of an air conditioning system.

14. The method according to claim 2, further comprising performing a maintenance step after the adjustment step where the target temperature of the surface is kept constant.

15. The method according to claim 3, wherein in the maintenance step the maintenance current is determined with reference to an ambient temperature.

16. The method according to claim 3, wherein in the maintenance step the maintenance current is determined with reference to a temperature differential in the Peltier element.

17. The method according to claim 3, wherein in the maintenance step the maintenance current is determined with reference to the target temperature of the surface.

18. The method according to claim 3, wherein in the maintenance step the maintenance current is determined with reference to physical characteristics of the Peltier element.

19. The method according to claim 3, wherein in the maintenance step the maintenance current is determined with reference to operating parameters of an air conditioning system.

20. A method for regulating a Peltier element, comprising:
applying a starting current to the Peltier element in a starting step;
subsequently cooling a surface that is heat-conductively connected to the Peltier element in a cooling step, wherein the surface is cooled to a target temperature in the cooling step;
applying a maintenance current to the Peltier element in an adjustment step after the cooling step, wherein the maintenance current is lower than the starting current; and
wherein, in a maintenance step after the cooling step and before the adjustment step, the maintenance current is determined with reference to at least one of an ambient temperature, a temperature differential in the Peltier element, the target temperature, physical characteristics of the Peltier element, and operating parameters of an air conditioning system.
